(19) United States
(12) Patent Application Publication
(10) Pub. No.: US 2024/0292685 A1
(43) Pub. Date: Aug. 29, 2024

(54) DISPLAY SUBSTRATE AND DISPLAY DEVICE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Biao LIU, Beijing (CN); Yi ZHANG, Beijing (CN); Tinghua SHANG, Beijing (CN); Jiangtao DENG, Beijing (CN); Jiaxing CHEN, Beijing (CN); Yixuan LONG, Beijing (CN); Zuoji NIU, Beijing (CN)

(21) Appl. No.: 18/024,076

(22) PCT Filed: Feb. 24, 2022
(86) PCT No.: PCT/CN2022/077663

§ 371 Date: Mar. 1, 2023

(51) Int. Cl. H10K 59/131; G09G 3/3233; H10K 59/121

(52) U.S. Cl. CPC H10K 59/131; G09G 3/3233; H10K 59/1213; G09G 2300/0819; G09G 2300/0842

(57) ABSTRACT

A display substrate and a display device are provided. The display substrate includes first voltage lines in multiple columns, and multiple rows and multiple columns of pixel driving circuits arranged on a base substrate; the pixel driving circuit includes a driving transistor and a compensation transistor; an orthographic projection of the first voltage line on the base substrate at least partially overlaps an orthographic projection of a gate electrode of the driving transistor on the base substrate; the gate electrode of the driving transistor is coupled to a first electrode of the compensation transistor through a first conductive connection portion; a second electrode of the compensation transistor is coupled to a first electrode of the driving transistor; an orthographic projection of the first voltage line on the base substrate at least partially overlaps an orthographic projection of the first conductive connection portion on the base substrate.

### TECHNICAL FIELD

The present disclosure relates to the field of display technology, in particular to a display substrate and a display device.

### BACKGROUND

In the related art, the anode pattern is used to shield the gate electrode of the driving transistor and the connection pattern coupled to the gate electrode of the driving transistor, which cannot improve the transmittance of the display panel while stabilizing the gate voltage of the driving transistor.

### SUMMARY

In one aspect, the present disclosure provides in some embodiments a display substrate, including: first voltage lines in a plurality of columns, and a plurality of rows and a plurality of columns of pixel driving circuits arranged on a base substrate: wherein the pixel driving circuit includes a driving transistor and a compensation transistor; an orthographic projection of the first voltage line on the base substrate at least partially overlaps an orthographic projection of a gate electrode of the driving transistor on the base substrate: the gate electrode of the driving transistor is coupled to a first electrode of the compensation transistor through a first conductive connection portion: a second electrode of the compensation transistor is coupled to a first electrode of the driving transistor: an orthographic projection of the first voltage line on the base substrate at least partially overlaps an orthographic projection of the first conductive connection portion on the base substrate.

Optionally, the orthographic projection of the first voltage line on the base substrate covers the orthographic projection of the first conductive connection portion on the base substrate.

Optionally, the orthographic projection of the first voltage line on the base substrate covers an orthographic projection of at least one gate electrode of the compensation transistor on the base substrate.

Optionally, the display substrate further comprises first initial voltage lines in a plurality of rows arranged on the base substrate: the pixel driving circuit further includes a first initialization transistor: a first electrode of the first initialization transistor is coupled to the first initial voltage line: the first electrode of the compensation transistor is coupled to a second electrode of the first initialization transistor: the orthographic projection of the first voltage line on the base substrate at least partially overlaps the orthographic projection of the first electrode of the compensation transistor on the base substrate: the orthographic projection of the first voltage line on the base substrate at least partially overlaps an orthographic projection of the second electrode of the first initialization transistor on the base substrate.

Optionally, the orthographic projection of the first voltage line on the base substrate covers the orthographic projection of the first electrode of the compensation transistor on the base substrate, and the orthographic projection of the second electrode of the first initialization transistor on the base substrate.

Optionally, the pixel driving circuit further comprises a storage capacitor: the gate electrode of the driving transistor is multiplexed as a first electrode plate of the storage capacitor: the orthographic projection of the first voltage line on the base substrate and the orthographic projection of a second electrode plate of the storage capacitor on the base substrate jointly cover the orthographic projection of the gate electrode of the driving transistor on the base substrate.

Optionally, the display substrate further includes scan lines in a plurality of rows arranged on the base substrate: wherein the compensation transistor is a double-gate transistor, and the compensation transistor includes a first gate electrode and a second gate electrode: the scan line includes a first protrusion portion and a first main portion extending along a first direction: the first gate electrode of the compensation transistor and the first main portion form an integral structure, and the second gate electrode of the compensation transistor and the first protrusion portion form an integral structure: the orthographic projection of the first voltage line on the base substrate covers an orthographic projection of the first gate electrode of the compensation transistor on the base substrate: the orthographic projection of the first voltage line on the base substrate does not overlap an orthographic projection of the second gate electrode of the compensation transistor on the base substrate: or, the orthographic projection of the first voltage line on the base substrate at least partially overlaps the orthographic projection of the second gate electrode of the compensation transistor on the base substrate.

Optionally, the pixel driving circuit further comprises a storage capacitor: a second electrode plate of the storage capacitor has a second protrusion portion, and an orthographic projection of the second protrusion portion on the base substrate at least partially overlaps an orthographic projection of a first active pattern on the base substrate: the first active pattern is an active pattern arranged between a first channel of the compensation transistor and a second channel of the compensation transistor.

Optionally, an orthographic projection of at least one channel of the compensation transistor on the base substrate at least partially overlaps an orthographic projection of the first conductive connection portion on the base substrate.

Optionally, the orthographic projection of the first voltage line on the base substrate covers an orthographic projection of at least one channel of the compensation transistor on the base substrate: a part of the first voltage line covering the first conductive connection portion and a part of the first voltage line covering at least one channel of the compensation transistor form an integral structure.

Optionally, the first conductive connection portion is coupled to the first electrode of the compensation transistor through a connection via hole: an orthographic projection of the connecting via hole on the base substrate is located on a side of the gate electrode of the compensation transistor away from a channel of the driving transistor.

Optionally, the display substrate further includes first initial voltage lines in a plurality of rows and data lines in a plurality columns arranged on the base substrate: wherein the first initial voltage line includes a third a protrusion portion and a second main portion extending along a first direction: an orthographic projection of the third protrusion portion on the base substrate is located between an orthographic projection of the data line on the base substrate and an orthographic projection of the first conductive connection portion on the base substrate.

Optionally, the display substrate further includes first initial voltage lines in a plurality of rows, second initial voltage lines in a plurality of rows, and reset control lines in a plurality of rows arranged on the base substrate: wherein a current pixel driving circuit is respectively coupled to a first initial voltage line in a current row, a second initial voltage line in the current row and a reset control line in the current row: a pixel driving circuit of a previous adjacent row is respectively coupled to a first initial voltage line in the previous adjacent row; the second initial voltage line in the previous adjacent row and the reset control line in the previous adjacent row: an orthographic projection of the second initial voltage line in the previous adjacent row on the base substrate, an orthographic projection of the reset control line in the current row on the base substrate, and an orthographic projection of the first initial voltage line in the current row on the base substrate are arranged in sequence along a second direction; the second initial voltage line is located on a same layer as the first initial voltage line, and the reset control line is located on a different layer from the second initial voltage line.

Optionally, the display substrate further includes light emitting control lines in a plurality of rows arranged on the base substrate: wherein the pixel driving circuit further comprises a first light emitting control transistor and a second light emitting control transistor: a gate electrode of the first light emitting control transistor, a gate electrode of the second light emitting control transistor and the light emitting control line form an integral structure: a first electrode of the first light emitting control transistor is coupled to the first voltage line, and a second electrode of the first light emitting control transistor is coupled to the second electrode of the driving transistor: a first electrode of the second light emitting control transistor is coupled to the first electrode of the driving transistor, and a second electrode of the second light emitting control transistor is coupled to an anode of a corresponding light emitting element.

Optionally, the display substrate further comprises second initial voltage lines in a plurality of rows and data lines in a plurality of columns arranged on the base substrate: both a first distance and a second distance are greater than a line width of the data line: the first distance is a shortest distance between an orthographic projection of electrodes of the first light emitting control transistor on the base substrate and an orthographic projection of the second initial voltage line on the base substrate: the electrodes of the first light emitting control transistor include a first electrode of the first light emitting control transistor and a second electrode of the first light emitting control transistor; the second distance is a shortest distance between an orthographic projection of a coupling portion between electrodes of the second light emitting control transistor and the anode of the corresponding light emitting element on the base substrate and the orthographic projection of the second initial voltage line on the base substrate.

Optionally, the display substrate further includes scan lines in a plurality of rows, first initial voltage lines in a plurality of rows, second initial voltage lines in a plurality of rows, and data lines in a plurality of columns arranged on the base substrate: wherein the pixel driving circuit further includes a data writing-in transistor, a second initialization transistor and a second light emitting control transistor: a gate electrode of the data writing-in transistor and a scanning line in a current row form an integral structure, a first electrode of the data writing-in transistor is coupled to the data line, a second electrode of the data writing-in transistor is coupled to the second electrode of the driving transistor: a gate electrode of the second initialization transistor is coupled to a reset control line in a next adjacent row, a first electrode of the second initialization transistor is coupled to a second initial voltage line in a current row, and a second electrode of the second initialization transistor is coupled to the second electrode of the second light emitting control transistor: the scanning line in the current row, the light emitting control line in the current row, the second initial voltage line in the current row and the reset control line in the next adjacent row are arranged in sequence along a second direction.

Optionally, the display substrate includes a camera area and a first transition area: at least part of pixel driving circuits in the plurality of rows and the plurality of columns of pixel driving circuits are arranged in the first transition area: the at least part of pixel driving circuit includes pixel driving circuits corresponding to the camera area and pixel driving circuits corresponding to the first transition area: the pixel driving circuits corresponding to the camera area are respectively coupled to an anode patterns arranged in the camera area through connection lines: the pixel driving circuits corresponding to the first transition area are coupled to an anode pattern arranged in the first transition area.

Optionally, the display substrate further comprises a second transition area and a normal display area: at least part of the pixel driving circuits included in the plurality of rows and the plurality of columns of pixel driving circuit are arranged in the normal display area, at least part of pixel driving circuits included in the plurality of rows and the plurality of columns of pixel driving circuits are arranged in the second transition area: the part of the pixel driving circuits arranged in the normal display area are coupled to an anode pattern arranged in the normal display area, and the part of the pixel driving circuits arranged in the second transition area are coupled to an anode pattern arranged in the second transition area.

Optionally, the display substrate further includes scanning lines in a plurality of rows and data lines in a plurality of column arranged on the base substrate: wherein the pixel circuit is electrically connected to a data line in a row: the compensation transistor is a double-gate transistor, and the compensation transistor includes a first gate electrode and a second gate electrode, and a first active pattern arranged between a first channel of the compensation transistor and a second channel of the compensation transistor: an orthographic projection of the first active pattern on the base substrate is located between an orthographic projection of the first gate electrode or the second gate electrode on the base substrate and an orthographic projection of a data line electrically connected to the pixel circuit on the base substrate.

In a second aspect, an embodiment of the present disclosure provides a display device including the display substrate.

Optionally, the display substrate includes a first transition area, a second transition area, and a normal display area: the display substrate includes a first pixel driving circuit arranged in the normal display area, a second pixel driving circuit arranged in the second transition area, and a third pixel driving circuit arranged in the first transition area: the data lines included in the display substrate and coupled to the first pixel driving circuit extend along a column direction: in the second transition area, the display substrate further includes data lines extending along a row direction and arranged between a light emitting control transistor included in the second pixel driving circuit and a second initialization voltage line coupled to the second pixel driving circuit: a data line coupled to the third pixel driving circuit and included in the display substrate is electrically connected to at least one data line extending along the row direction.

Optionally, an area of an orthographic projection of an anode connection portion in the at least one third pixel driving circuit arranged in the second transition area and included in the display substrate is larger than an area of an orthographic projection of an anode connection portion in the second pixel driving circuit on the base substrate; the anode connection portion is a connection conductive portion between the pixel driving circuit and a corresponding anode pattern.

### BRIEF DESCRIPTION OF THE DRAWINGS

FIG. 1 is a circuit diagram of a pixel driving circuit included in a display substrate according to at least one embodiment of the present disclosure;

FIG. 2 is a layout diagram of the active layer in FIG. 9;

FIG. 3 is a layout diagram of the first gate metal layer in FIG. 9;

FIG. 4 is a layout diagram of a second gate metal layer in FIG. 9;

FIG. 5 is a layout diagram of the first source-drain metal layer in FIG. 9;

FIG. 6 is a layout diagram of a second source-drain metal layer in FIG. 9;

FIG. 7 is a superimposed schematic view of the active layer, the first gate metal layer and the second gate metal layer in FIG. 9;

FIG. 8 is a superimposed schematic diagram of the active layer, the first gate metal layer, the second gate metal layer, the first gate metal layer and the second gate metal layer in FIG. 9;

FIG. 9 is a layout diagram of a pixel driving circuit in a display substrate according to at least one embodiment of the present disclosure;

FIG. 10 is a superimposed schematic diagram of the second source-drain metal layer and the first gate metal layer in FIG. 9;

FIG. 11 is a layout diagram of the first gate metal layer in FIG. 9;

FIG. 12 is a superimposed schematic diagram of the active layer and the second gate metal layer in FIG. 9;

FIG. 13 is a schematic diagram of area division of a display substrate according to at least one embodiment of the present disclosure;

FIG. 14 is a schematic diagram of adding data line winding on the basis of FIG. 13;

FIG. 15 is a schematic diagram of adding a conductive layer on the basis of the display substrate shown in FIG. 9;

FIG. 16A is a layout diagram of the conductive layer in FIG. 15;

FIG. 16B is a superimposed schematic diagram of the second source-drain metal layer and the conductive layer in FIG. 15.

FIG. 17 is a layout diagram of the first source-drain metal layer in the second transition area of the display substrate;

FIG. 18 is a schematic diagram of adding a conductive layer in the normal display area on the basis of at least one embodiment of the display substrate shown in FIG. 8;

FIG. 19 is a schematic diagram of the positional relationship between each pixel driving circuit and the anode layer in the normal display area;

FIG. 20 is a layout diagram of the anode layer in FIG. 19;

FIG. 21 is a cross-sectional view of a display substrate according to at least one embodiment of the present disclosure.

### DETAILED DESCRIPTION

The following will clearly and completely describe the technical solutions in the embodiments of the present disclosure with reference to the accompanying drawings. Apparently, the described embodiments are only some of the embodiments of the present disclosure, not all of them. Based on the embodiments in the present disclosure, all other embodiments obtained by a person skilled in the art without creative work belong to the protection scope of the present disclosure.

The transistors used in all the embodiments of the present disclosure may be triodes, thin film transistors or field effect transistors or other devices with the same characteristics. In the embodiments of the present disclosure, in order to distinguish the two electrodes of the transistor other than the gate electrode, one of the electrodes is referred to as a first electrode, and the other electrode is referred to as a second electrode.

In actual operation, when the transistor is a thin film transistor or a field effect transistor, the first electrode may be a drain electrode, and the second electrode may be a source electrode; or, the first electrode may be a source electrode, the second electrode may be a drain electrode.

An embodiment of the present disclosure provides a display substrate, the display substrate includes a plurality of rows and a plurality of columns of pixel driving circuits arranged on a base substrate;

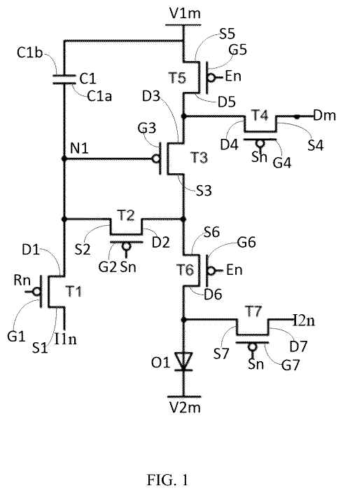

As shown in FIG. 1, at least one embodiment of the pixel driving circuit may include a driving transistor T3, a compensation transistor T2, a data writing-in transistor T4, a first initialization transistor T1, a second initialization transistor T7, and a first light emitting control transistor T5, a second light emitting control transistor T6, a storage capacitor C1 and an organic light emitting diode O1;

A gate electrode G3 of the driving transistor T3 is coupled to a first electrode S2 of the compensation control transistor T2;

A first electrode plate C1a of the storage capacitor C1 is coupled to the gate electrode G3 of the driving transistor T3, and the second electrode plate C1b of the storage capacitor C1 is coupled to a first voltage line V1m;

A gate electrode G2 of the compensation control transistor T2 is coupled to the scan line Sn; a first electrode S2 of the compensation control transistor T2 is coupled to a second electrode D1 of the first initialization transistor T1; a second electrode D2 of the compensation control transistor T2 is coupled to the first electrode S3 of the drive transistor T3;

A gate electrode G4 of the data writing-in transistor T4 is coupled to the scan line Sn, a first electrode S4 of the data writing-in transistor T4 is coupled to the data line Dm, a second electrode D4 of the data writing-in transistor T4 is coupled to the second electrode D3 of the driving transistor T3;

A gate electrode of the first initialization transistor T1 is coupled to the reset control line Rn, and a first electrode S1 of the first initialization transistor T1 is coupled to a first initial voltage line I1n;

A gate electrode of the second initialization transistor T7 is coupled to the scan line Sn, a first electrode S7 of the second initialization transistor T7 is coupled to a second initial voltage line I2n, and a second electrode of the second initialization transistor T7 D7 is coupled to the second electrode D6 of the second light emitting control transistor T6;

Both a gate electrode G5 of the first light emitting control transistor T5 and a gate electrode G6 of the second light emitting control transistor T6 are coupled to the light emitting control line En;

A first electrode S5 of the first light emitting control transistor T5 is coupled to the first voltage line V1m, and a second electrode D5 of the first light emitting control transistor T5 is coupled to the second electrode D3 of the driving transistor T3;

A first electrode S6 of the second light emitting control transistor T6 is coupled to the first electrode S3 of the driving transistor T3, and a second electrode D6 of the second light emitting control transistor T6 is coupled to the anode of the organic light emitting diode O1;

A cathode of the OLED O1 is coupled to the second voltage line V2m.

In FIG. 1, the one labeled N1 is the first node, and the first node N1 is coupled to the gate electrode G3 of the driving transistor T3.

In the pixel circuit shown in FIG. 1, all transistors may be p-type transistors, but not limited thereto.

In the pixel circuit shown in FIG. 1, the scan line Sn may be the scan line in the nth row, the reset control line Rn may be the reset control line in the nth row, and the first initial voltage line I1n may be the first initial voltage line in the nth row, the second initial voltage line I2n may be the second initial voltage line in the nth row, the light emitting control line En may be the light emitting control line in the nth row, and n is a positive integer;

The data line Dm may be the data line in the mth column, the first voltage line V1m may be the first voltage line in the mth column, and m is a positive integer.

In at least one embodiment of the present disclosure, the first voltage line may be a power supply voltage line, but not limited thereto.

In at least one embodiment of the present disclosure, the reset control line Rn, the light emitting control line En, and the first initial voltage line I1n may extend along a first direction, and the data line Dm may extend along a second direction, the first direction intersects the second direction;

The first direction may be a horizontal direction, and the second direction may be a vertical direction; but not limited to this.

In at least one embodiment of the present disclosure, the first direction may be a row direction, and the second direction may be a column direction, but not limited thereto.

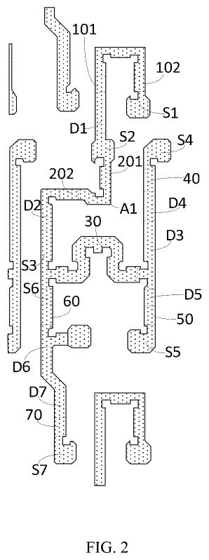

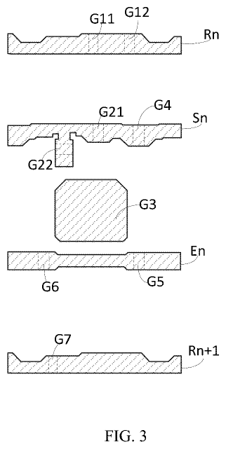

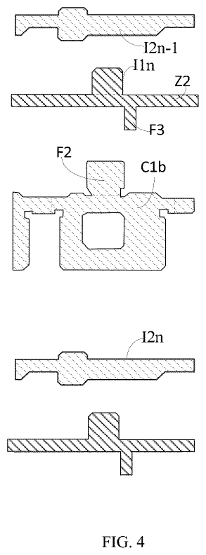

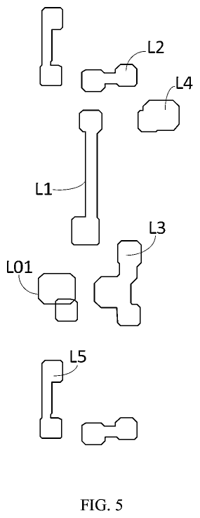

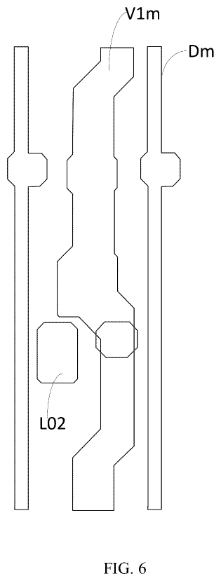

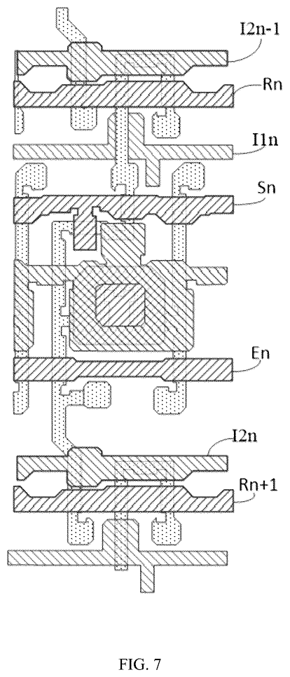

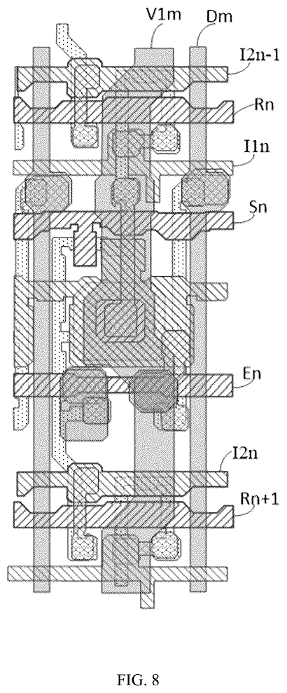

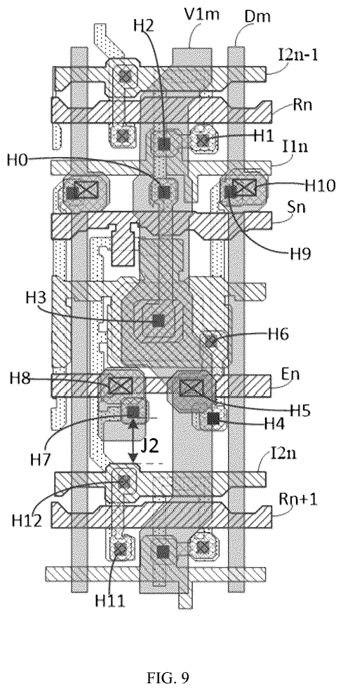

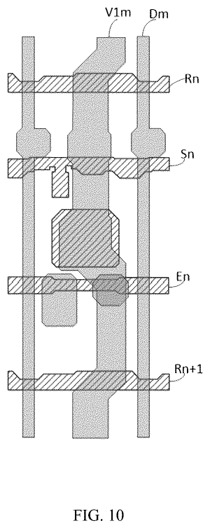

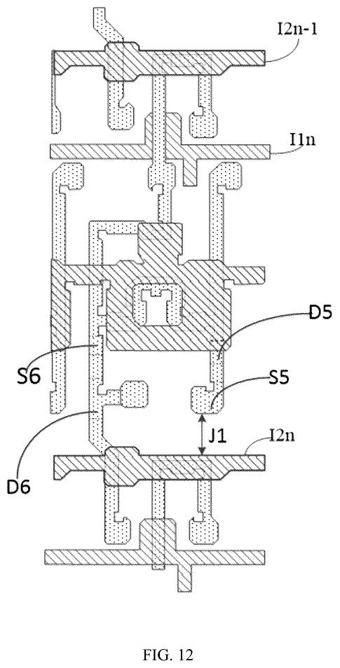

FIG. 9 is a layout diagram of a pixel driving circuit in a display substrate according to an embodiment of the present disclosure, FIG. 2 is a layout diagram of an active layer in FIG. 9, and FIG. 3 is the layout of the first gate metal layer in FIG. 9, FIG. 4 is the layout of the second gate metal layer in FIG. 9, FIG. 5 is the layout of the first source-drain metal layer in FIG. 9, FIG. 6 is the layout of the second source-drain metal layer in FIG. 9, FIG. 7 is a superimposed schematic diagram of the active layer, the first gate metal layer and the second gate metal layer in FIG. 9, FIG. 8 is superimposed schematic diagram of the active layer, the first gate metal layer, the second gate metal layer, the first gate metal layer and the second gate metal layer in FIG. 9, FIG. 10 is a superimposed schematic diagram of the second source-drain metal layer and the first gate metal layer in FIG. 9, and FIG. 12 is the superimposed schematic diagram of the active layer and the second gate metal layer in FIG. 9.

In at least one embodiment of the present disclosure, T1 and T2 may be double-gate transistors, but not limited thereto.

In FIG. 2, the one labeled 101 is the first channel portion of the first initialization transistor T1, the one labeled 102 is the second channel portion of the first initialization transistor T1; the one labeled 201 is the first channel portion of the compensation transistor T2, the one labeled 202 is the second channel portion of the compensation transistor T2;

The one labeled 30 is the channel of the driving transistor T3; the one labeled 40 is the channel of the data writing-in transistor T4; the one labeled 50 is the channel of the first light emitting control transistor T5, the one labeled 60 is the channel of the second light emitting control transistor T6, the one labeled 70 is the channel of the second initialization transistor T7.

In FIG. 3, the one labeled G11 is the first gate electrode of the first initialization transistor T1, the one labeled G12 is the second gate electrode of the first initialization transistor T1, and the one labeled G21 is the first gate electrode of the compensation transistor T2, the one labeled G22 is the second gate electrode of the compensation transistor T2;

The one labeled G3 is the gate electrode of the driving transistor T3, the one labeled G4 is the gate electrode of the data writing-in transistor T4, the one labeled G5 is the gate electrode of the first light emitting control transistor T5, and the one labeled G6 is the gate electrode of the second light emitting control transistor T6, and the one labeled G7 is the gate electrode of the second initialization transistor T7.

In FIG. 3, the one labeled Sn is the scanning line, the one labeled Rn is the reset control line, the one labeled En is the light emitting control line, and the one labeled Rn+1 is the reset control line in a next adjacent row.

In FIG. 4, the one labeled I1n is the first initial voltage line, the one labeled I2n is the second initial voltage line, the one labeled I2n−1 is the reset control line in a previous adjacent row, and the one labeled C1b is the second electrode plate of the storage capacitor C1.

In FIG. 5, the one labeled L1 is the first conductive connection portion.

In FIG. 6, the one labeled V1m is the first voltage line, and the one labeled Dm is the data line.

The display substrate described in the embodiment of the present disclosure includes first voltage lines in a plurality of columns and a plurality of rows and a plurality of columns of pixel driving circuits arranged on the base substrate; the pixel driving circuit includes a driving transistor and a compensation transistor;

An orthographic projection of the first voltage line on the base substrate at least partially overlaps the orthographic projection of the gate electrode of the driving transistor on the base substrate;

The gate electrode of the driving transistor is coupled to the first electrode of the compensation transistor through a first conductive connection portion; the second electrode of the compensation transistor is coupled to the first electrode of the driving transistor;

An orthographic projection of the first voltage line on the base substrate at least partially overlaps an orthographic projection of the first conductive connection portion on the base substrate.

In the display substrate described in the embodiments of the present disclosure, the first voltage line shields at least part of the gate electrode of the driving transistor, and the first voltage line shields at least part of the first conductive connection portion (the first conductive connection portion is a conductive pattern used to connect the gate electrode of the driving transistor and the second electrode of the compensation transistor, the first conductive connection portion is coupled to the first node), so that the gate voltage of the driving transistor can be stabilized and the transmittance of the display panel is improved.

Optionally, the orthographic projection of the first voltage line on the base substrate covers the orthographic projection of the first conductive connection portion on the base substrate, so as to stabilize the potential of the first node.

The display substrate described in the embodiments of the present disclosure includes first voltage lines in a plurality of columns and a plurality of rows and a plurality of columns of pixel driving circuits arranged on the base substrate; as shown in FIG. 1, the pixel driving circuit includes a driving transistor T3 and compensation transistor T2;

As shown in FIGS. 2-12, the orthographic projection of the first voltage line V1m on the base substrate partly overlaps the orthographic projection of the gate electrode G3 of the driving transistor on the base substrate;

The gate electrode G3 of the driving transistor T3 is coupled to the first electrode S2 of the compensation transistor T2 through the first conductive connection portion L1; the second electrode D2 of the compensation transistor T2 is coupled to the first electrode S3 of the driving transistor T3;

The orthographic projection of the first voltage line V1m on the base substrate covers the orthographic projection of the first conductive connection portion L1 on the base substrate.

The display substrate according to at least one embodiment of the present disclosure uses the first voltage line V1m to shield a part of the gate electrode G3 of the driving transistor T3, and uses the first voltage line V1m to cover the first conductive connection portion L1 (the first conductive connection portion L1 is a conductive pattern for connecting the gate electrode G3 of the driving transistor and the second electrode D2 of the compensation transistor T2, the first conductive connection portion L1 is coupled to the first node N1), so that the potential of the first node N1 is stabled, the transmittance of the display panel is improved.

In at least one embodiment of the present disclosure, the first voltage line V1m may be a vertical line, and the first voltage line V1m not only serves as a power supply voltage line, but also shield the gate electrode of the driving transistor T3 and the first conductive connection portion L1, which saves space in the horizontal direction and is beneficial to increase PPI (Pixels Per Inch, pixel density).

In related art, for Full Display with Camera (FDC) display products, in the FDC lead area, the parasitic capacitance between the ITO layer and the first node N1 is relatively large, which is prone to Mura (uneven display) defects, so the FDC display product needs to use a stable signal to completely shield the first node N1.

In at least one embodiment of the present disclosure, the orthographic projection of the first voltage line on the base substrate covers the orthographic projection of at least one gate electrode of the compensation transistor on the base substrate, that is, the orthographic projection of the first voltage line on the base substrate covers the orthographic projection of at least one channel of the compensation transistor on the base substrate, so as to ensure the stability of the light emitting of the compensation transistor.

As shown in FIGS. 2-12, the compensation transistor T2 may be a double-gate transistor; the orthographic projection of the first voltage line V1m on the base substrate covers the orthographic projection of the first gate electrode G21 of the compensation transistor T2 on the base substrate, that is, the orthographic projection of the first voltage line V1m on the base substrate covers the orthographic projection of the first channel 201 of the compensation transistor T2 on the base substrate, so as to improve the stability of the light emitting of the compensation transistor T2.

In at least one embodiment of the present disclosure, the display substrate further includes scanning lines in a plurality of rows and data lines in a plurality of columns arranged on the base substrate: the pixel circuit is electrically connected to the data line in a row;

As shown in FIG. 2-FIG. 12, the compensation transistor T2 is a double-gate transistor, the compensation transistor T2 includes a first gate electrode and a second gate electrode, and the first active pattern A1 arranged between the first channel 201 of the compensation transistor T2 and the second channel 202 of the compensation transistor T2;

The orthographic projection of the first active pattern A1 on the base substrate is located between the orthographic projection of the first gate electrode G21 of the compensation transistor T2 or the orthographic projection of the second gate electrode G22 of the compensation transistor T2 on the base substrate and the orthographic projection of the data line Dm electrically connected to the pixel circuit on the base substrate.

The display substrate according to at least one embodiment of the present disclosure may further include first initial voltage lines in a plurality of rows arranged on the base substrate; the pixel driving circuit further includes a first initialization transistor;

A first electrode of the first initialization transistor is coupled to the first initial voltage line;

The first electrode of the compensation transistor is coupled to the second electrode of the first initialization transistor;

The orthographic projection of the first voltage line on the base substrate at least partially overlaps the orthographic projection of the first electrode of the compensation transistor on the base substrate: the orthographic projection of the first voltage line on the base substrate at least partially overlaps the orthographic projection of the second electrode of the first initialization transistor on the base substrate, so as to stabilize the potential of the first node.

In at least one embodiment of the present disclosure, both the first electrode of the compensation transistor and the second electrode of the first initialization transistor are coupled to the gate electrode of the driving transistor, and thus the first voltage line is used to at least partially cover the first electrode of the compensation transistor and the second electrode of the first initialization transistor, so as to stabilize the potential of the first node.

The orthographic projection of the first voltage line on the base substrate covers the orthographic projection of the first electrode of the compensation transistor on the base substrate, and the orthographic projection of the second electrode of the first initialization transistor on the base substrate, so as to stabilize the potential of the first node.

The display substrate according to at least one embodiment of the present disclosure may further include first initial voltage lines in a plurality of rows arranged on the base substrate: as shown in FIG. 1, the pixel driving circuit further includes a first initialization transistor T1;

As shown in FIGS. 2-12, the first electrode S1 of the first initialization transistor T1 is coupled to the first initial voltage line I1n;

As shown in FIG. 2, the first electrode S2 of the compensation transistor T2 is coupled to the second electrode D1 of the first initialization transistor T1;

As shown in FIG. 2-FIG. 12, the first electrode S1 of the first initialization transistor T1 is coupled to the second conductive connection portion L2 through the first via hole H1, and the second conductive connection portion L2 is coupled to the first initial voltage line I1n through the second via hole H2.

As shown in FIGS. 2-12, the orthographic projection of the first voltage line V1m on the base substrate covers the orthographic projection of the first electrode S2 of the compensation transistor T2 on the base substrate, and the orthographic projection of the second electrode D1 of the first initialization transistor T1 on the base substrate, so as to stabilize the potential of the first node N1.

In at least one embodiment of the present disclosure, the first conductive connection portion is coupled to the first electrode of the compensation transistor through a connection via hole;

The orthographic projection of the connection via hole on the base substrate is located on a side of the gate electrode of the compensation transistor away from the channel of the driving transistor, so that the connection via hole moves upward without occupying the space in a horizontal direction, so that the dimension in the horizontal direction of the display substrate can be compressed.

As shown in FIG. 2-FIG. 12, the gate electrode G3 of the driving transistor T3 is coupled to the first conductive connection portion L1 through the third via hole H3, and the first conductive connection portion L1 is coupled to the first electrode S2 of the compensation transistor T2 through the connection via hole H0.

The orthographic projection of the connecting via hole H0 on the base substrate is located on a side of the first gate electrode G21 of the compensation transistor T2 away from the orthographic projection of the channel 30 of the driving transistor T3 on the base substrate, so that the connection via hole H0 is moved upward, thereby compressing the size of the display substrate in the horizontal direction.

In at least one embodiment of the present disclosure, as shown in FIGS. 1-12, the pixel driving circuit further includes a storage capacitor C1; the gate electrode G3 of the driving transistor T3 is multiplexed as the first electrode plate of the storage capacitor C1;

As shown in FIG. 2-FIG. 12, the orthographic projection of the first voltage line V1m on the base substrate and the orthographic projection of the second electrode plate C1b of the storage capacitor C1 on the base substrate together cover the orthographic projection of the gate electrode G3 of the driving transistor T3 on the base substrate.

In the related art, the second electrode plate C1b of the storage capacitor C1 partially covers the gate electrode G3 of the driving transistor T3, but since the gate electrode of the driving transistor T3 needs to be coupled to the film layer above it, an opening needs to be provided on the second electrode plate C1b of the storage capacitor C1, so the second electrode plate C1b of the storage capacitor C1 cannot completely cover the gate electrode G3 of the driving transistor T3. Based on this, in at least one embodiment of the present disclosure, the first voltage line V1m covers the opening, so that the orthographic projection of the first voltage line V1m on the base substrate and the orthographic projection of the second electrode plate C1b of the storage capacitor C1 on the base substrate jointly covers the orthographic projection of the gate electrode G3 of the driving transistor T3 on the base substrate, which can stabilize the gate voltage of the driving transistor T3 and ensure the display effect.

The display substrate according to at least one embodiment of the present disclosure may further include scan lines in a plurality of rows arranged on the base substrate: as shown in FIG. 2-FIG. 12, the compensation transistor T2 is a double-gate transistor, and the first gate electrode of the compensation transistor T2 is marked as G21, and the second gate electrode of the compensation transistor T2 is marked as G22;

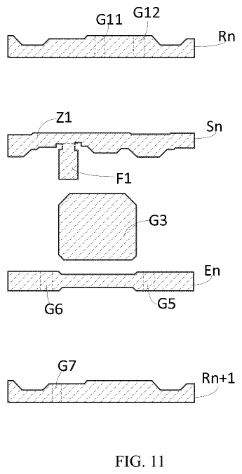

As shown in FIG. 11, the scan line Sn includes a first protrusion portion F1 and a first main portion Z1 extending along a first direction;

As shown in FIG. 3 and FIG. 11, the first gate electrode G21 of the compensation transistor T2 and the first main portion Z1 form an integral structure, and the second gate electrode G22 of the compensation transistor T2 and the first protrusion portion F1 form an integral structure;

As shown in FIG. 8, the orthographic projection of the first voltage line V1m on the base substrate covers the orthographic projection of the first gate electrode G21 of the compensation transistor T2 on the base substrate, that is, the orthographic projection of the first voltage line V1m on the base substrate covers the orthographic projection of the first channel 201 of the compensation transistor T2 on the base substrate, so as to improve the light emitting stability of the compensation transistor T2.

Optionally, the orthographic projection of the first voltage line on the base substrate does not overlap the orthographic projection of the second gate electrode of the compensation transistor on the base substrate: or, the orthographic projection of the first voltage line on the base substrate at least partially overlaps the orthographic projection of the second gate electrode of the compensation transistor on the base substrate.

In at least one embodiment of the present disclosure, as shown in FIG. 8, the orthographic projection of the first voltage line V1m on the base substrate and the orthographic projection of the second gate electrode G22 of the compensation transistor T2 on the base substrate may not overlap: but it is not limited to this.

In actual operation, the orthographic projection of the first voltage line V1m on the base substrate may at least partially overlap the orthographic projection of the second gate electrode G22 of the compensation transistor T2 on the base substrate, that is, the orthographic projection of the first voltage line V1m on the base substrate may at least partially overlap the orthographic projection of the second channel 202 of the compensation transistor T2 on the base substrate, so as to improve the light emitting stability of the compensation transistor T2.

In at least one embodiment of the present disclosure, the second electrode plate of the storage capacitor has a second protrusion portion, and the orthographic projection of the second protrusion portion on the base substrate at least partially overlaps the orthographic projection of the first active pattern on the base substrate, so as to improve the voltage stability of a middle node of the compensation transistor.

Optionally, as shown in FIG. 4, the second electrode plate C1b of the storage capacitor C1 has a second protrusion portion F2. As shown in FIG. 7, the orthographic projection of the second protrusion portion F2 on the base substrate partially overlaps the orthographic projection of the first active pattern A1 on the base substrate, so as to improve the voltage stability of the middle node of the compensation transistor T2;

As shown in FIG. 2, the first active pattern A1 is an active pattern arranged between the first channel 201 of the compensation transistor T2 and the second channel 202 of the compensation transistor.

In specific implementation, when the compensation transistor T2 is not turned on, the voltage on the data line Dm jumps and the voltage on the scan line Sn jumps, which will have an impact on the first active pattern A1, so that when the compensation transistor T2 is turned on, it will affect the voltage of the middle node of the compensation transistor T2 (the middle node of the compensation transistor T2 is the node of the compensation transistor T2 electrically connected to the first active pattern A1). Based on this, in at least one embodiment of the present disclosure, the orthographic projection of the second protrusion portion F2 on the base substrate partially overlaps the orthographic projection of the first active pattern A1 on the base substrate, so as to improve the voltage stability of the middle node of the compensation transistor T2.

As shown in FIGS. 2-12, in at least one embodiment of the present disclosure, the first protrusion portion F1 protrudes toward the gate electrode G3 of the driving transistor T3, and the second protrusion portion F2 protrudes toward the scanning line Sn, so that the space on the right side of the first protrusion portion F1 is used to arrange the second protrusion portion F2, which can save vertical space.

In the related art, the conductive connection pattern arranged on the first source-drain metal layer and coupled to the first voltage line extends in the first direction to cover the first active pattern, which will increase the vertical space of the pixel driving circuit. Based on this, in at least one embodiment of the present disclosure, the second protruding portion F2 covers the first active pattern A1, so as to save the vertical space.

Optionally, the orthographic projection of at least one channel of the compensation transistor on the base substrate at least partially overlaps the orthographic projection of the first conductive connection portion on the base substrate, so that the first conductive connection portion at least partially covers at least one channel of the compensation transistor, so as to improve the light emitting stability of the compensation transistor.

As shown in FIGS. 2-12, in at least one embodiment of the present disclosure, the orthographic projection of the first conductive connection portion L1 on the base substrate covers the orthographic projection of the first channel 201 of the compensation transistor T2 on the base substrate, so as to improve the light emitting stability of the compensation transistor T2.

In at least one embodiment of the present disclosure, the orthographic projection of the first voltage line on the base substrate covers the orthographic projection of at least one channel of the compensation transistor on the base substrate;

The part of the first voltage line covering the first conductive connection portion and the part of the first voltage line covering at least one channel of the compensation transistor form an integral structure, so that the same first voltage line can cover at least one channel of the compensation transistor and the first conductive connection portion at the same time, so as to improve the light emitting stability of the compensation transistor and stabilize the potential of the first node.

As shown in FIG. 8, the part of the first voltage line V1m covering the first conductive connection portion L1 and the part of the first voltage line V1m covering the first channel 201 of the compensation transistor T2 form an integral structure, so that the first voltage line V1m covers the first conductive connection portion L1 and the first channel 201 of the compensation transistor T2 at the same time.

The display substrate according to at least one embodiment of the present disclosure further includes first initial voltage lines in a plurality of rows and data lines in a plurality columns arranged on the base substrate; as shown in FIG. 4, the first initial voltage line I1n includes a third a protrusion portion F3 and a second main portion Z2 extending along the first direction;

As shown in FIGS. 2-12, the orthographic projection of the third protrusion portion F3 on the base substrate is located between the orthographic projection of the data line Dm on the base substrate and the orthographic projection of the first conductive connection portion L1 on the base substrate, so that the data line Dm is separated from the first conductive connection portion L1, to shield the influence of the data voltage change on the data line Dm on the potential of the first node, and improve the crosstalk.

As shown in FIGS. 2-12, the third protrusion portion F3 protrudes toward the scan line Sn.

The display substrate according to at least one embodiment of the present disclosure further includes scan lines in a plurality of rows arranged on the base substrate: as shown in FIGS. 2-12, the orthographic projection of the third protrusion portion F3 on the base substrate is located between the orthographic projection of the second main portion Z2 on the base substrate and the orthographic projection of the scan line Sn on the base substrate;

The orthographic projection of the third protrusion portion F3 on the base does not overlap the orthographic projection of the scan line Sn on the base substrate.

In at least one embodiment of the present disclosure, the third protrusion portion F3 is arranged between the second main portion Z2 and the scan line Sn, and there is a certain distance between the orthographic projection of the third protrusion portion F3 on the base substrate and the orthographic projection of the scan line Sn on the base substrate.

In at least one embodiment of the present disclosure, the display substrate further includes first initial voltage lines in a plurality of rows, second initial voltage lines in a plurality of rows, and reset control lines in a plurality of rows arranged on the base substrate; the current pixel driving circuit is respectively coupled to the first initial voltage line in the current row, the second initial voltage line in the current row and the reset control line in the current row: the pixel driving circuit of the previous adjacent row is respectively coupled to the first initial voltage line in the previous adjacent row and the second initial voltage line in the previous adjacent row and the reset control line in the previous adjacent row;

The orthographic projection of the second initial voltage line in the previous adjacent row on the base substrate, the orthographic projection of the reset control line in the current row on the base substrate, and the orthographic projection of the first initial voltage line in the current row on the base substrate are arranged in sequence along the second direction;

The second initial voltage line is located on the same layer as the first initial voltage line, and the reset control line is located on a different layer from the second initial voltage line.

In specific implementation, both the first initial voltage line and the second initial voltage line may be located on the second gate metal layer, the reset control line may be located on the first gate metal layer, and the orthographic projection of the reset control line in the current row on the base substrate is located between the orthographic projection of initial voltage lines in the previous adjacent row on the base substrate and the orthographic projection of the first initial voltage line in the current row on the base substrate, which can save vertical space.

In actual operation, on the same metal layer, there is a minimum Space limit between two signal lines, that is, on the same second gate metal layer, there is a minimum Space limitation between the first initial voltage line and the second initial voltage line, and in at least one embodiment of the present disclosure, the reset control line is arranged on the first gate metal layer, so as to save vertical space.

In FIG. 4, the one labeled I2n-1 is the second initial voltage line in the previous adjacent row, the one labeled I1n is the first initial voltage line in the current row, and the one labeled I2n is the second initialization voltage line in the current row;

In FIG. 3, the one labeled Rn is the reset control line in the current row, the one labeled Sn is the scanning line in the current row, the one labeled En is the light emitting control line in the current row, and the one labeled Rn+1 is the reset control line in the next adjacent row.

As shown in FIG. 7, the orthographic projection of the second initial voltage line I2n-1 in the previous adjacent row on the base substrate, the orthographic projection of the reset control line Rn in the current row on the base substrate, and the orthographic projections of the first initial voltage lines I1n in the current row on the base are arranged sequentially along the second direction.

The display substrate according to at least one embodiment of the present disclosure may further include light emitting control lines in a plurality of rows arranged on the base substrate: as shown in FIG. 1, the pixel driving circuit further includes a first light emitting control transistor T5 and the second light emitting control transistor T6;

As shown in FIG. 3, the gate electrode G5 of the first light emitting control transistor T5, the gate electrode G6 of the second light emitting control transistor T6 and the light emitting control line En form an integral structure;

As shown in FIG. 2-FIG. 12, the first electrode S5 of the first light emitting control transistor T5 is coupled to the third conductive connection portion L3 through the fourth via hole H4, and the third conductive connection portion L3 is coupled to the first voltage line V1m through the fifth via hole H5, so that the first electrode S5 of the first light emitting control transistor T5 is coupled to the first voltage line V1m;

As shown in FIG. 2-FIG. 12, the third conductive connection portion L3 is also coupled to the second electrode plate C1b of the storage capacitor C1 through the sixth via hole H6; the second electrode D5 of the first light emitting control transistor T5 is coupled to the second electrode D3 of the driving transistor T3;

As shown in FIG. 2-FIG. 12, the first electrode S6 of the second light emitting control transistor T6 is coupled to the first electrode S3 of the driving transistor T3, and the second electrode D6 of the second light emitting control transistor T6 is coupled to the first connection conductive portion L01 through the seventh via hole H7, and the first connection conductive portion L01 is coupled to the second connection conductive portion L02 through the eighth via hole H8.

In at least one embodiment of the present disclosure, in the normal display area and the second transition area, the second connection conductive portion L02 is coupled to the anode of the corresponding light emitting element through a via hole;

In the first transition area, the second connection conductive portion L02 in the pixel driving circuit corresponding to the first transition area is coupled to the anode of the corresponding light-emitting element through a via hole, the second connection conductive portion L02 in the pixel driving circuit corresponding to the camera area is coupled to the anode of the corresponding light emitting element through a connection line.

In at least one embodiment of the present disclosure, the first connection conductive portion L01 is located in the first source-drain metal layer, the second connection conductive part L02 is located in the second source-drain metal layer, and the connection wire can be located in the conductive layer, the anode of the light emitting element may be located in the anode layer.

In specific implementation, the display substrate according to at least one embodiment of the present disclosure may include an active layer, a first gate metal layer, a second gate metal layer, a first source-drain metal layer, a second source-drain metal layer, a conductive layer and an anode layer arranged in sequence away from the base substrate, the conductive layer may be an ITO layer, but not limited thereto.

In at least one embodiment of the present disclosure, the light emitting element may be an organic light emitting diode, but not limited thereto.

Optionally, the display substrate further includes second initial voltage lines in a plurality of rows and data lines in a plurality of columns arranged on the base substrate;

Both the first distance and the second distance are greater than the line width of the data line;

The first distance is the shortest distance between the orthographic projection of the electrodes of the first light emitting control transistor on the base substrate and the orthographic projection of the second initial voltage line on the base substrate. The electrodes of the first light emitting control transistor includes a first electrode of the first light emitting control transistor and a second electrode of the first light emitting control transistor;

The second distance is the shortest distance between the orthographic projection of a coupling portion between the electrode of the second light emitting control transistor and the anode of the corresponding light emitting element and the orthographic projection of the second initial voltage line on the base substrate.

In at least one embodiment of the present disclosure, the shortest distance between the orthographic projection of the electrode of the first light emitting control transistor on the base substrate and the orthographic projection of the second initial voltage line on the base substrate, and the shortest distance between the orthographic projection of the electrode of the second light emitting control transistor on the base substrate and the orthographic projection of the second initial voltage line on the base substrate are both greater than the line width of the data line, so that the date line can be arranged between the light emitting control transistor and the second initial voltage line (in the second transition area, a space for winding the data line needs to be provided).

As shown in FIG. 2-FIG. 12, the orthographic projection of the second electrode D5 of the first light emitting control transistor T5 on the base substrate is located a side of the orthographic projection of the first electrode S5 of the first light emitting control transistor T5 on the base substrate away from the orthographic projection of the second initial voltage line I2n on the base substrate:

The orthographic projection of the first electrode S6 of the second light emitting control transistor T6 on the base substrate is located at a side of an orthographic projection of the second electrode D6 of the second light emitting control transistor T6 on the base substrate away from the orthographic projection of the second initial voltage line I2n on the base substrate;

As shown in FIG. 12, the first distance J1 is the shortest distance between the orthographic projection of the first electrode S5 of the first light emitting control transistor T5 on the base substrate and the orthographic projection of the second initial voltage line I2n on the base substrate.

As shown in FIG. 9, the second distance J2 is the shortest distance between the orthographic projection of the coupling portion between the second electrode D6 of the second light emitting control transistor T6 and the anode of the corresponding light emitting element on the base substrate and the orthographic projection of the second initial voltage line I2n on the base substrate.

As shown in FIG. 5, FIG. 6 and FIG. 9, the second electrode D6 of the second light emitting control transistor T6 is coupled to the first connection conductive portion L01 through the seventh via hole H7, and the first connection conductive portion L01 is coupled to the second connection conductive part L02 through the eighth via hole H8, and the second connection conductive portion L02 is coupled to the anode of the corresponding light emitting element through the via hole;

In FIG. 9, the location of the seventh via hole H7 is located may be the coupling portion between the second electrode D6 of the second light emitting control transistor T6 and the anode of the corresponding light emitting element.

The display substrate according to at least one embodiment of the present disclosure may further include scan lines in a plurality of rows, first initial voltage lines in a plurality of rows, second initial voltage lines in a plurality of rows, and data lines in a plurality of columns arranged on the base substrate: as shown in FIG. 1, the pixel driving circuit further includes a data writing-in transistor T4 and a second initialization transistor T7;

As shown in FIG. 3, the gate electrode G4 of the data writing-in transistor T4 and the scanning line Sn in the current row form an integral structure;

As shown in FIG. 2-FIG. 10, the first electrode S4 of the data writing-in transistor T4 is coupled to the fourth conductive connection portion L4 through the ninth via hole H9, and the fourth conductive connection portion L4 is coupled to the data line Dm through the tenth via hole H10, so that the first electrode S4 of the data writing-in transistor T4 is coupled to the data line Dm;

As shown in FIG. 3, the gate electrode G7 of the second initialization transistor T7 and the reset control line Rn+1 in the next adjacent row form an integral structure;

As shown in FIG. 2-FIG. 10, the first electrode S7 of the second initialization transistor T7 is coupled to the fifth conductive connection portion L5 through the eleventh via hole H11, and the fifth conductive connection portion L5 is coupled to the second initial voltage line I2n in the current row through the twelfth via hole H12, so that the first electrode S7 of the second initialization transistor T7 is coupled to the second initial voltage line I2n in the current row;

As shown in FIG. 2, the second electrode D7 of the second initialization transistor T7 is coupled to the second electrode D6 of the second light emitting control transistor T6;

As shown in FIG. 7, the scan line Sn in the current row, the light emitting control line En in the current row, the second initial voltage line I2n in the current row and the reset control line Rn+1 in the next adjacent row are arranged in sequence along the second direction.

In at least one embodiment of the present disclosure, in the peripheral area of the display substrate other than the display area, the reset control line Rn+1 in the next adjacent row is electrically connected to the scan line Sn in the current row.

As shown in FIG. 2, the active layer of the driving transistor T3, the active layer of the compensation transistor T2, the active layer of the first initialization transistor T1, the active layer of the data writing-in transistor T4, the active layer of the first light emitting control transistor T5, the active layer of the second light emitting control transistor T6, and the active layer of the second initialization transistor T7 are formed by a continuous semiconductor layer;

The channel of the first initialization transistor T1, the channel of the compensation transistor T2, the channel 30 of the driving transistor T3, the channel 60 of the second light emitting control transistor T6, and the channel of the second initialization transistor T7 are arranged in sequence along the second direction;

The first channel portion 201 of the compensation transistor T2 and the channel 40 of the data writing-in transistor T4 are arranged along a first direction;

The channel 60 of the second light emitting control transistor T6 and the channel 50 of the first light emitting control transistor T5 are arranged along a first direction;

The channel of the first initialization transistor T1 includes: a first channel portion 101 of the first initialization transistor T1 and a second channel portion 102 of the first initialization transistor T1;

The channel of the compensation transistor T2 includes: a first channel portion 201 of the compensation transistor T2 and a second channel portion 202 of the second initialization transistor T2.

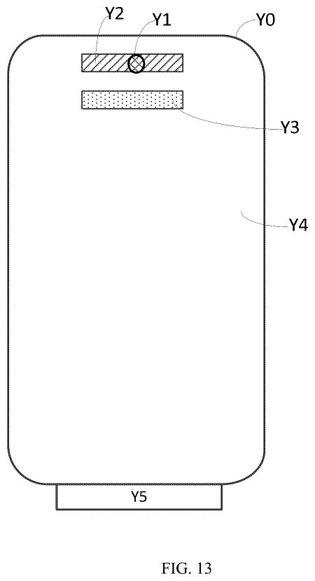

The display substrate described in at least one embodiment of the present disclosure can be applied to FDC display products. As shown in FIG. 13, the display substrate includes a display area Y0, the display area includes a camera area Y1, a first transition area Y2, a second transition area Y3 and a normal display area Y4;

The first transition area Y2 includes a transition area set on the left side of the camera area Y1, and a transition area set on the right side of the camera area Y1;

The second transition area Y3 is arranged below the first transition area Y2;

The normal display area Y4 is an area in the display area other than the camera area Y1, the first transition area Y2 and the second transition area Y3.

In FIG. 13, the one labeled Y5 is the area where the driver integrated circuit is arranged.

In at least one embodiment of the present disclosure, a light-emitting element is provided in the camera area Y1; the light-emitting element includes an anode pattern, and the anode pattern is located on the anode layer;

The pixel driving circuit corresponding to the camera area Y1, the pixel driving circuit corresponding to the first transition area Y2, and the light-emitting element are arranged in the first transition area Y2; the pixel driving circuit corresponding to the camera area Y1 is respectively coupled to the anode pattern arranged in the camera area Y1 through connection lines, and the pixel driving circuit corresponding to the first transition area Y2 is coupled to the anode pattern arranged in the first transition area Y2.

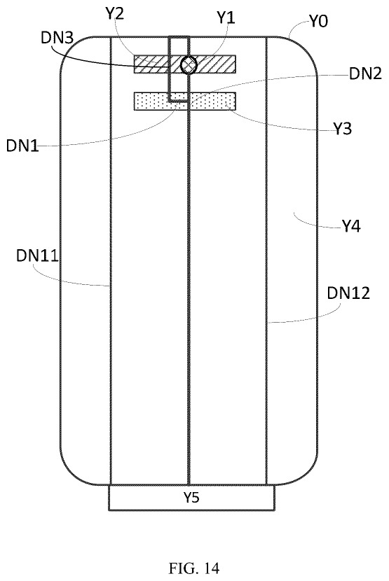

As shown in FIG. 14, in the area included in the display area Y0 other than the camera area Y1, there are longitudinally extended data lines; in the camera area Y1, there are no data lines; therefore, it is necessary to arrange horizontally extended data lines and vertically extended data lines in the second transition area Y3, so as to connect the data lines disconnected by the camera area Y2 in the vertical direction through the data line arranged in the second transition area Y3.

In FIG. 14, the one labeled DN1 is data lines arranged in the second transition area Y3 and extending along the horizontal direction, and one labeled DN2 is data lines arranged in the second transition area Y3 and extending along the vertical direction.

In FIG. 14, DN11 is the first data line arranged in the normal display area, and DN12 is the second data line arranged in the normal display area. DN11 and DN22 extend along the vertical direction.

In at least one embodiment shown in FIG. 14, there may be multiple data lines in each area.

In at least one embodiment shown in FIG. 14, the horizontal direction may be a row direction, and the vertical direction may be a column direction, but not limited thereto.

In at least one embodiment of the present disclosure, the display substrate includes a camera area and a first transition area: at least part of the pixel driving circuits in the plurality of rows and the plurality of columns of pixel driving circuits are arranged in the first transition area;

The at least part of the pixel driving circuit includes pixel driving circuits corresponding to the camera area and pixel driving circuits corresponding to the first transition area;

The pixel driving circuits corresponding to the camera area are respectively coupled to the anode patterns arranged in the camera area through connection lines.

The pixel driving circuits corresponding to the first transition area are coupled to the anode pattern arranged in the first transition area.

During specific implementation, no pixel driving circuit is provided in the camera area, so as not to block the camera arranged in the camera area, and the pixel driving circuit corresponding to the camera area is arranged in the first transition area, the pixel driving circuits corresponding to the camera area are respectively coupled to the anode patterns arranged in the camera area through connection lines.

Optionally, the pixel driving circuit includes a second light emitting control transistor, and the display substrate includes an active layer, a first source-drain metal layer, a second source-drain metal layer, a conductive layer, and an anode layer that are arranged in sequence away from the base substrate; the anode pattern is located on the anode layer; the second electrode of the second light emitting control transistor included in the pixel driving circuit is coupled to the corresponding anode pattern;

The second electrode of the second light emitting control transistor is coupled to the first connection conductive portion, and the first connection conductive portion is coupled to the second connection conductive portion: the second connection conductive portion is coupled to the corresponding anode pattern thought a connection line;

The second electrode of the second light emitting control transistor is located in the active layer, the first connection conductive portion is located in the first source-drain metal layer, the second connection conductive portion is located in the second source-drain metal layer, and the connecting lines are formed on the conductive layer.

Optionally, the conductive layer may be an indium tin oxide (ITO) layer, but not limited thereto.

Optionally, the first transition area includes at least one first area and at least one second area, and the first area and the second area are arranged alternately along the second direction;

At least one column of pixel driving circuits corresponding to the first transition area are arranged in the first area, and at least one column of pixel driving circuits corresponding to the camera head area are arranged in the second area.

In a specific implementation, in the first transition area, at least one column of pixel driving circuits corresponding to the first transition area may be arranged every other column of pixel driving circuits corresponding to the camera area: for example, a column of pixel driving circuits corresponding to the camera area is arranged every two columns of pixel driving circuits corresponding to the first transition area, but not limited thereto.

In at least one embodiment of the present disclosure, the display substrate further includes a camera area and a second transition area: at least some of the pixel driving circuits included in the plurality of rows and the plurality of columns of pixel driving circuits are arranged in the normal display area, and at least part of the pixel driving circuits included in the plurality of rows and the plurality of columns of pixel driving circuits are arranged in the second transition area;

A part of the pixel driving circuits arranged in the normal display area are coupled to the anode pattern arranged in the normal display area, and a part of the pixel driving circuits arranged in the second transition area are coupled to the anode pattern arranged in the second transition area.

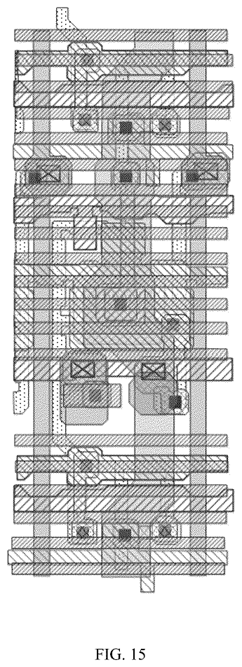

FIG. 15 is a schematic diagram of adding a conductive layer on the basis of the display substrate shown in FIG. 9; FIG. 15 corresponds to the first transition area of the display substrate, and a plurality of connection lines extending along the first direction are arranged on the conductive layer, and the pixel driving circuits corresponding to the camera area are respectively coupled to the anode patterns arranged in the camera area through the connection lines.

In at least one embodiment of the present disclosure, the first direction may be a horizontal direction, and the first direction may be a row direction, but not limited thereto.

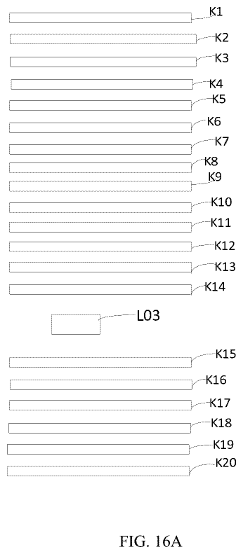

FIG. 16A is a layout diagram of the conductive layer in FIG. 15.

In FIG. 16A, the one marked K1 is the first connection line, the one marked K2 is the second connection line, the one marked K3 is the third connection line, and the one marked K4 is the fourth connection line. The one marked K5 is the fifth connection line, the one marked K6 is the sixth connection line, the one marked K7 is the seventh connection line, the one marked K8 is the eighth connection line, and the one marked K9 is the ninth connection line, the one marked K10 is the tenth connection line, the one marked K11 is the eleventh connection line, the one marked K12 is the twelfth connection line, and the one marked K13 is the thirteenth connection line, the one marked K14 is the fourteenth connection line, the one marked K15 is the fifteenth connection line, the one marked K16 is the sixteenth connection line, the one marked K17 is the seventeenth connection line, and the one marked K18 is the eighteenth connection line, the one marked K19 is the nineteenth connection line, the one marked K20 is the twentieth connection line: the one marked L03 is the third connection conductive portion.

FIG. 16B is a superimposed schematic diagram of the second source-drain metal layer and the conductive layer in FIG. 15.

In at least one embodiment of the present disclosure, considering the distance between the connection lines, the connection lines can be made through two or more conductive layers to serve as anode connection lines;

The connection lines included in different conductive layers may be substantially non-overlapped, or partially overlapped: or, the connection lines included in non-adjacent conductive layers may be at least partially overlapped.

For example, when the display substrate includes a first conductive layer, a second conductive layer and a third conductive layer, and the first conductive layer, the second conductive layer and the third conductive layer are arranged along a direction away from the base substrate, the orthographic projection of the connection lines included in the first conductive layer on the base substrate and the orthographic projection of the connection lines included in the third conductive layer on the base substrate may at least partially overlap, and the orthographic projection of the connection lines included in the first conductive layer on the base substrate and the orthographic projection of the connection lines included in the second conductive layer on the base substrate may not overlap, and the orthographic projection of the connection lines included in the second conductive layer on the base substrate and the orthographic projection of the connection lines included in the third conductive layer on the base substrate may not overlap, which is used to adjust the coupling capacitance between different pixel anodes.

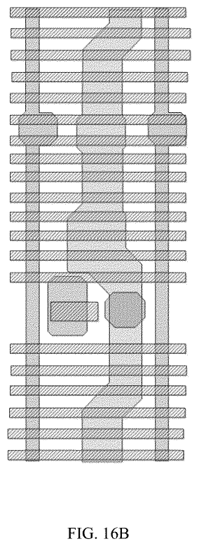

In at least one embodiment of the present disclosure, in the second transition area, as shown in FIG. 17, the data line DK extended along the horizontal direction is arranged in the first source-drain metal layer, so as to wind the data lines and the data line disconnected by the camera area in the vertical direction is connected by the data line DK in the second transition area, the layout of the first source-drain metal layer in the second transition area is different from other areas, but the layout of the active layer can be as shown in FIG. 2, and the layout of the first gate metal layer can be as shown in FIG. 3, the layout of the second gate metal layer may be as shown in FIG. 4, and the layout of the second source-drain metal layer may be as shown in FIG. 6, but not limited thereto.

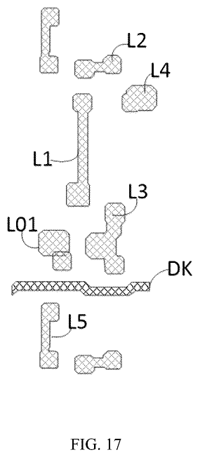

FIG. 18 is a schematic diagram of adding a conductive layer on the basis of the display substrate shown in FIG. 8 in the normal display area.

In FIG. 18, the one labeled L03 is the third connection conductive portion, and the one labeled H13 is the thirteenth via hole: the third connection conductive portion L03 is located in the conductive layer, and the third connection conductive portion L03 is coupled to the second connection conductive portion L02 through the thirteenth via hole H13, and the third connection conductive portion L03 is also coupled to the anode pattern arranged in the normal display area.

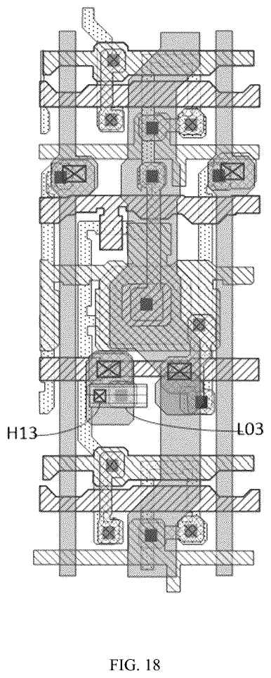

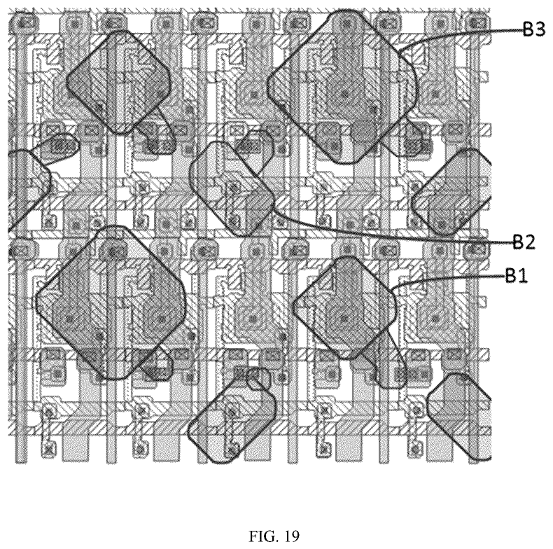

FIG. 19 is a schematic diagram of the positional relationship between each pixel driving circuit and the anode layer in the normal display area. FIG. 20 is a layout diagram of the anode layer in FIG. 19. In FIG. 19 and FIG. 20, the anode of the red OLED is labeled B1, the anode of the green OLED is labeled B2, and the anode of the blue OLED is labeled B3. As shown in FIG. 19, the anode of each organic light emitting diode only needs to be coupled to the second light emitting control transistor in the pixel driving circuit, and there is no need to shield the gate electrode of the driving transistor, the conductive pattern coupled to the driving transistor, and, the channel of the compensation transistor.

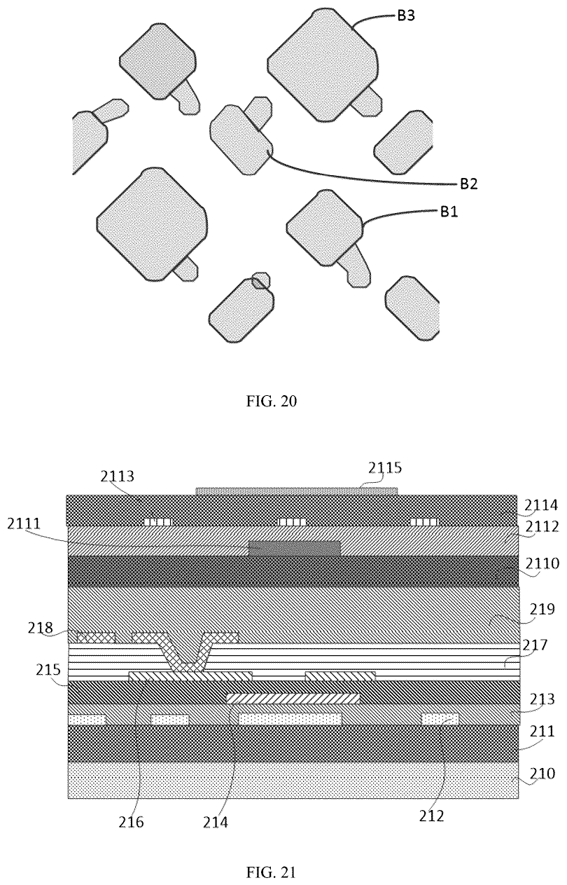

As shown in FIG. 21, the display substrate according to at least one embodiment of the present disclosure includes a base substrate 210, and a buffer layer 211, an active layer 212, a first gate insulating layer 213, a first gate metal layer 214, a second gate insulating layer 215, a second gate metal layer 216, an interlayer dielectric layer 217, a first source-drain metal layer 218, a passivation layer 219, a first planarization layer 2110, a second source-drain metal layer 2111, a second planarization layer 2112, a conductive layer 2113, a third planarization layer 2114 and an anode layer 2115 that are stacked on the base substrate.

In at least one embodiment of the present disclosure, the display substrate may include at least two conductive layers arranged between the second planarization layer 2112 and the anode layer 2115, and a planarization layer may be arranged between adjacent two conductive layers, which is conducive to the connection lines between more pixels.

In at least one embodiment of the present disclosure, two layers of conductive layers may be arranged between the second planarization layer and the anode layer, that is, a first conductive layer, a third planarization layer, a second conductive layer, a fourth planarization layer, and an anode layer are arranged on a side of the second planarization layer away from the base substrate: or,

Three layers of conductive layers may be arranged between the second planarization layer and the anode layer, that is, a first conductive layer, a third planarization layer, a second conductive layer, a fourth planarization layer, a third conductive layer, a fifth planarization layer and the anode layer are arranged on a side of the second planarization layer away from the base substrate.

The display device described in the embodiment of the present disclosure includes the above-mentioned display substrate.

The display substrate according to at least one embodiment of the present disclosure includes a first transition area, a second transition area, and a normal display area: the display substrate incudes a first pixel driving circuit in the normal display area, a second pixel driving circuit in the second transition area, and a third pixel driving circuit arranged in the first transition area;

The data lines included in the display substrate and coupled to the first pixel driving circuit extend along the column direction;

In the second transition area, the display substrate further includes data lines extending along the row direction and arranged between a light emitting control transistor included in the second pixel driving circuit and a second initialization voltage line coupled to the second pixel driving circuit;

The data line coupled to the third pixel driving circuit included in the display substrate is electrically connected to at least one data line extending along the row direction.

In at least one embodiment of the present disclosure, the row direction may be a horizontal direction, and the column direction may be a vertical direction, but not limited thereto.

Exemplarily, as shown in FIG. 14, the first data line DN11 and the second data line DN12 are data lines coupled to the first pixel driving circuit, and the first data line DN11 and the second data line extend along the column direction.

As shown in FIG. 17, a data line DK extending along the horizontal direction is provided in the second transition area to perform data line winding, so that the data line disconnected by the camera area in the vertical direction are connected by the data line DK arranged in the second transition area.

Exemplarily, as shown in FIG. 14, a data line DN3 coupled to the third pixel circuit is provided in the first transition area, and the data line is electrically connected to the data line DN1 extending in the horizontal direction.

In at least one embodiment of the present disclosure, an area of the orthographic projection of a anode connection portion in the at least one third pixel driving circuit arranged in the second transition area included in the display substrate is larger than an area of the orthographic projection of the anode connection portion in the second pixel driving circuit on the base substrate;

The anode connection portion is a connection conductive portion between the pixel driving circuit and the corresponding anode pattern.

In at least one embodiment of the present disclosure, as shown in FIG. 5, FIG. 6 and FIG. 9, in the second transition area, in the second pixel driving circuit, the first electrode S6 of the second light emitting control transistor T6 is coupled to the first electrode S3 of the driving transistor T3, the second electrode D6 of the second light emitting control transistor T6 is coupled to the first connection conductive portion L01 through the seventh via hole H7, and the first connection conductive portion L01 is coupled to the second connection conductive portion L02 through the eighth via hole H8, and the second connection conductive portion L02 is coupled to the anode of the corresponding light emitting element through the via hole. That is, in the second transition area, the anode transition portion includes a first connection conductive portion and a second connection conductive portion.

In at least one embodiment of the present disclosure, as shown in FIG. 5, FIG. 6, FIG. 9, FIG. 15 and FIG. 16, in the first transition area, in the third pixel driving circuit corresponding to the camera area, the first electrode S6 of the second light emitting control transistor T6 is coupled to the first electrode S3 of the driving transistor T3, and the second electrode D6 of the second light emitting control transistor T6 is coupled to the first connection conductive portion L01 through the seventh via hole H7, the first connection conductive portion L01 is coupled to the second connection conductive portion L02 through the eighth via hole H8, and the second connection conductive portion L02 is coupled to the anode of the corresponding light-emitting element through a connection line. That is, in the first transition area, for the third pixel driving circuit corresponding to the camera area, the anode connection portion includes a first connection conductive portion, a second connection conductive portion and the connection line.

To sum up, in the first transition area, the area of the orthographic projection of the anode connection portion in the third pixel driving circuit corresponding to the camera area on the base substrate is larger than the area of the orthographic projection of the anode connection portion in the second pixel driving circuit on the base substrate.

The display device provided by the embodiments of the present disclosure may be any product or component with a display function, such as a mobile phone, a tablet computer, a television, a monitor, a notebook computer, a digital photo frame, a navigator, and the like.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A display substrate, comprising first voltage lines in a plurality of columns, and a plurality of rows and a plurality of columns of pixel driving circuits arranged on a base substrate; wherein the pixel driving circuit includes a driving transistor and a compensation transistor;
an orthographic projection of the first voltage line on the base substrate at least partially overlaps an orthographic projection of a gate electrode of the driving transistor on the base substrate;
the gate electrode of the driving transistor is coupled to a first electrode of the compensation transistor through a first conductive connection portion; a second electrode of the compensation transistor is coupled to a first electrode of the driving transistor;
an orthographic projection of the first voltage line on the base substrate at least partially overlaps an orthographic projection of the first conductive connection portion on the base substrate.

2. The display substrate according to claim 1, wherein the orthographic projection of the first voltage line on the base substrate covers the orthographic projection of the first conductive connection portion on the base substrate.

3. The display substrate according to claim 1, wherein the orthographic projection of the first voltage line on the base substrate covers an orthographic projection of at least one gate electrode of the compensation transistor on the base substrate.

4. The display substrate according to claim 1, wherein the display substrate further comprises first initial voltage lines in a plurality of rows arranged on the base substrate; the pixel driving circuit further includes a first initialization transistor; a first electrode of the first initialization transistor is coupled to the first initial voltage line;
the first electrode of the compensation transistor is coupled to a second electrode of the first initialization transistor;
the orthographic projection of the first voltage line on the base substrate at least partially overlaps the orthographic projection of the first electrode of the compensation transistor on the base substrate; the orthographic projection of the first voltage line on the base substrate at least partially overlaps an orthographic projection of the second electrode of the first initialization transistor on the base substrate.

5. The display substrate according to claim 4, wherein the orthographic projection of the first voltage line on the base substrate covers the orthographic projection of the first electrode of the compensation transistor on the base substrate, and the orthographic projection of the second electrode of the first initialization transistor on the base substrate.

6. The display substrate according to claim 1, wherein the pixel driving circuit further comprises a storage capacitor; the gate electrode of the driving transistor is multiplexed as a first electrode plate of the storage capacitor;
the orthographic projection of the first voltage line on the base substrate and the orthographic projection of a second electrode plate of the storage capacitor on the base substrate jointly cover the orthographic projection of the gate electrode of the driving transistor on the base substrate.

7. The display substrate according to claim 3, further comprising scan lines in a plurality of rows arranged on the base substrate; wherein the compensation transistor is a double-gate transistor, and the compensation transistor includes a first gate electrode and a second gate electrode;
the scan line includes a first protrusion portion and a first main portion extending along a first direction;
the first gate electrode of the compensation transistor and the first main portion form an integral structure, and the second gate electrode of the compensation transistor and the first protrusion portion form an integral structure;
the orthographic projection of the first voltage line on the base substrate covers an orthographic projection of the first gate electrode of the compensation transistor on the base substrate;
the orthographic projection of the first voltage line on the base substrate does not overlap an orthographic projection of the second gate electrode of the compensation transistor on the base substrate; or, the orthographic projection of the first voltage line on the base substrate at least partially overlaps the orthographic projection of the second gate electrode of the compensation transistor on the base substrate.

8. The display substrate according to claim 7, wherein the pixel driving circuit further comprises a storage capacitor; a second electrode plate of the storage capacitor has a second protrusion portion, and an orthographic projection of the second protrusion portion on the base substrate at least partially overlaps an orthographic projection of a first active pattern on the base substrate;
the first active pattern is an active pattern arranged between a first channel of the compensation transistor and a second channel of the compensation transistor.

9. The display substrate according to claim 1, wherein an orthographic projection of at least one channel of the compensation transistor on the base substrate at least partially overlaps an orthographic projection of the first conductive connection portion on the base substrate.

10. The display substrate according to claim 1, wherein the orthographic projection of the first voltage line on the base substrate covers an orthographic projection of at least one channel of the compensation transistor on the base substrate;
a part of the first voltage line covering the first conductive connection portion and a part of the first voltage line covering at least one channel of the compensation transistor form an integral structure.

11. The display substrate according to claim 1, wherein the first conductive connection portion is coupled to the first electrode of the compensation transistor through a connection via hole;
an orthographic projection of the connecting via hole on the base substrate is located on a side of the gate electrode of the compensation transistor away from a channel of the driving transistor.

12. The display substrate according to claim 1, further comprising includes first initial voltage lines in a plurality of rows and data lines in a plurality columns arranged on the base substrate; wherein the first initial voltage line includes a third a protrusion portion and a second main portion extending along a first direction;
an orthographic projection of the third protrusion portion on the base substrate is located between an orthographic projection of the data line on the base substrate and an orthographic projection of the first conductive connection portion on the base substrate.

13. The display substrate according to claim 1, further comprising first initial voltage lines in a plurality of rows, second initial voltage lines in a plurality of rows, and reset control lines in a plurality of rows arranged on the base substrate; wherein a current pixel driving circuit is respectively coupled to a first initial voltage line in a current row, a second initial voltage line in the current row and a reset control line in the current row; a pixel driving circuit of a previous adjacent row is respectively coupled to a first initial voltage line in the previous adjacent row, the second initial voltage line in the previous adjacent row and the reset control line in the previous adjacent row;
an orthographic projection of the second initial voltage line in the previous adjacent row on the base substrate, an orthographic projection of the reset control line in the current row on the base substrate, and an orthographic projection of the first initial voltage line in the current row on the base substrate are arranged in sequence along a second direction;
the second initial voltage line is located on a same layer as the first initial voltage line, and the reset control line is located on a different layer from the second initial voltage line.

14. The display substrate according to claim 1, further comprising light emitting control lines in a plurality of rows arranged on the base substrate; wherein the pixel driving circuit further comprises a first light emitting control transistor and a second light emitting control transistor;
a gate electrode of the first light emitting control transistor, a gate electrode of the second light emitting control transistor and the light emitting control line form an integral structure;
a first electrode of the first light emitting control transistor is coupled to the first voltage line, and a second electrode of the first light emitting control transistor is coupled to the second electrode of the driving transistor;
a first electrode of the second light emitting control transistor is coupled to the first electrode of the driving transistor, and a second electrode of the second light emitting control transistor is coupled to an anode of a corresponding light emitting element, wherein the display substrate further comprises second initial voltage lines in a plurality of rows and data lines in a plurality of columns arranged on the base substrate;
both a first distance and a second distance are greater than a line width of the data line;
the first distance is a shortest distance between an orthographic projection of electrodes of the first light emitting control transistor on the base substrate and an orthographic projection of the second initial voltage line on the base substrate; the electrodes of the first light emitting control transistor include a first electrode of the first light emitting control transistor and a second electrode of the first light emitting control transistor;
the second distance is a shortest distance between an orthographic projection of a coupling portion between electrodes of the second light emitting control transistor and the anode of the corresponding light emitting element on the base substrate and the orthographic projection of the second initial voltage line on the base substrate.

15. (canceled)

16. The display substrate according to claim 1, further comprising scan lines in a plurality of rows, first initial voltage lines in a plurality of rows, second initial voltage lines in a plurality of rows, and data lines in a plurality of columns arranged on the base substrate; wherein the pixel driving circuit further includes a data writing-in transistor, a second initialization transistor and a second light emitting control transistor;
a gate electrode of the data writing-in transistor and a scanning line in a current row form an integral structure, a first electrode of the data writing-in transistor is coupled to the data line, a second electrode of the data writing-in transistor is coupled to the second electrode of the driving transistor;
a gate electrode of the second initialization transistor is coupled to a reset control line in a next adjacent row, a first electrode of the second initialization transistor is coupled to a second initial voltage line in a current row, and a second electrode of the second initialization transistor is coupled to the second electrode of the second light emitting control transistor;
the scanning line in the current row, the light emitting control line in the current row, the second initial voltage line in the current row and the reset control line in the next adjacent row are arranged in sequence along a second direction.

17. The display substrate according to claim 1, wherein the display substrate includes a camera area and a first transition area; at least part of pixel driving circuits in the plurality of rows and the plurality of columns of pixel driving circuits are arranged in the first transition area;
the at least part of pixel driving circuit includes pixel driving circuits corresponding to the camera area and pixel driving circuits corresponding to the first transition area;
the pixel driving circuits corresponding to the camera area are respectively coupled to an anode patterns arranged in the camera area through connection lines;
the pixel driving circuits corresponding to the first transition area are coupled to an anode pattern arranged in the first transition area, wherein the display substrate further comprises a second transition area and a normal display area; at least part of the pixel driving circuits included in the plurality of rows and the plurality of columns of pixel driving circuit are arranged in the normal display area, at least part of pixel driving circuits included in the plurality of rows and the plurality of columns of pixel driving circuits are arranged in the second transition area;
the part of the pixel driving circuits arranged in the normal display area are coupled to an anode pattern arranged in the normal display area, and the part of the pixel driving circuits arranged in the second transition area are coupled to an anode pattern arranged in the second transition area.

18. (canceled)

19. The display substrate according to claim 3, further comprising scanning lines in a plurality of rows and data lines in a plurality of column arranged on the base substrate; wherein the pixel circuit is electrically connected to a data line in a row;
the compensation transistor is a double-gate transistor, and the compensation transistor includes a first gate electrode and a second gate electrode, and a first active pattern arranged between a first channel of the compensation transistor and a second channel of the compensation transistor;
an orthographic projection of the first active pattern on the base substrate is located between an orthographic projection of the first gate electrode or the second gate electrode on the base substrate and an orthographic projection of a data line electrically connected to the pixel circuit on the base substrate.

20. A display device comprising the display substrate according to claim 1.

21. The display device according to claim 20, wherein the display substrate includes a first transition area, a second transition area, and a normal display area; the display substrate includes a first pixel driving circuit arranged in the normal display area, a second pixel driving circuit arranged in the second transition area, and a third pixel driving circuit arranged in the first transition area;
the data lines included in the display substrate and coupled to the first pixel driving circuit extend along a column direction;
in the second transition area, the display substrate further includes data lines extending along a row direction and arranged between a light emitting control transistor included in the second pixel driving circuit and a second initialization voltage line coupled to the second pixel driving circuit;
a data line coupled to the third pixel driving circuit and included in the display substrate is electrically connected to at least one data line extending along the row direction.

22. The display device according to claim 21, wherein an area of an orthographic projection of an anode connection portion in the at least one third pixel driving circuit arranged in the second transition area and included in the display substrate is larger than an area of an orthographic projection of an anode connection portion in the second pixel driving circuit on the base substrate;
the anode connection portion is a connection conductive portion between the pixel driving circuit and a corresponding anode pattern.
